(19) United States
(12) Patent Application Publication
(10) Pub. No.: US 2006/0263954 A1
(43) Pub. Date: Nov. 23, 2006

(54) Method of forming thin film transistor

(75) Inventors: Jiun-Jye Chang, Hsinchu City (TW); Chia-Yu Chen, Jhubei City (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: AU Optronics Corp.

(21) Appl. No.: 11/268,935

(22) Filed: Nov. 8, 2005

(30) Foreign Application Priority Data
May 19, 2005 (TW) 94116271

(51) Int. Cl. H01L 21/84

(52) U.S. Cl. 438/151; 438/609

(57) ABSTRACT

A method of forming a thin film transistor on a substrate. The method comprises forming a pattern layer on the substrate, forming a gate dielectric layer over the pattern layer, forming a first conductor pattern on the gate dielectric layer, forming an interlayer dielectric layer on the first conductor layer and the gate dielectric layer, forming a transparent oxide pattern on the interlayer dielectric layer, etching the interlayer dielectric layer and the gate dielectric layer, doping the pattern layer at high dosage to form source/drain regions, and forming second conductor patterns respectively in contact with the source/drain regions.

### BACKGROUND

The invention relates to a thin film transistor and, in particular, to a method of forming a thin film transistor with fewer mask layers.

FIG. 1 shows a conventional thin film transistor. The conventional thin film transistor has a top-gate structure but no lightly-doped drain(LDD) structure. Fabrication thereof requires at least six mask layers. A first mask layer is used in forming a poly-silicon pattern 101 on a substrate. Thereafter, an oxide layer 103 is formed over the poly-silicon pattern 101. A second mask layer is used in forming a gate electrode 105 on the oxide layer 103. A high-dose ion implantation is performed to form source/drain regions 107. Following formation of the source/drain regions, an interlayer dielectric layer 109 is formed on the gate electrode 105 and the oxide layer 103. A third mask is used in forming contact holes 111 in the interlayer dielectric layer 109 and the oxide layer 103. A metal layer 113 is deposited to form interconnection to the source/drain regions. A fourth mask is subsequently used to pattern the metal layer 113. A passivation layer 114 is deposited and a fifth mask is used in forming contact holes in the passivation layers. Finally, a Indium-Tin-Oxide(ITO) layer 117 is deposited and a sixth mask layer is used to form interconnection to the metal layer 113.

FIG. 2 shows another conventional thin film transistor. The conventional thin film transistor has a top-gate structure and a lightly-doped drain structure. Fabrication thereof is similar to the mentioned process but differs in that seven masks are required. The original second mask is used to form a gate electrode 105 and the gate electrode is used as a hard mask to implant low-dose impuries in the poly-silicon pattern in this case. Following the low-dose ion implantation, the additional mask is used to form source/drain regions 108 and lightly-doped drain regions 108.

### SUMMARY

Methods of forming a thin film transistor on a substrate comprise forming a pattern layer on the substrate, forming a gate dielectric layer over the pattern layer, forming a first conductor pattern on the gate dielectric layer, forming an interlayer dielectric layer on the first conductor layer and the gate dielectric layer, forming a transparent oxide pattern on the interlayer dielectric layer, etching the interlayer dielectric layer and the gate dielectric layer, doping the pattern layer at high dosage to form source/drain regions, and forming second conductor patterns respectively in contact with the source/drain regions.

The invention utilizes a transparent oxide pattern to perform self-aligned etching and doping. The process is simplified and number of masks required is reduced. Furthermore, the transparent oxide pattern is utilized to define the lightly-doped drain regions.

### BRIEF DESCRIPTION OF THE DRAWINGS

FIG. 1 shows a conventional thin film transistor.

FIG. 2 shows another conventional thin film transistor.

FIG. 3 shows a cross section of a thin film transistor formed by a method according to an embodiment of the invention.

FIGS. 4A-4I collectively show a method of forming a thin film transistor according to an embodiment of the invention.

FIG. 5 shows a cross section of a thin film transistor formed by a method according to another embodiment of the invention.

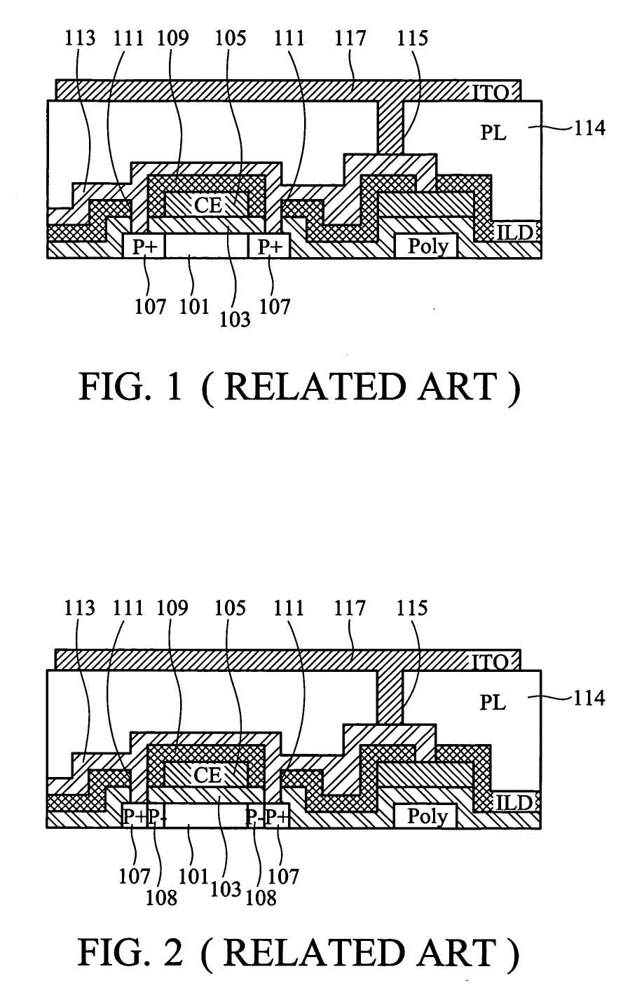

### DETAILED DESCRIPTION

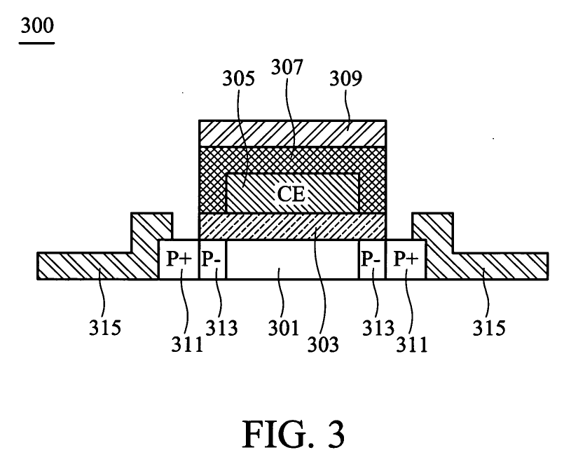

An embodiment of the invention provides a method of forming a thin film transistor on a substrate. A cross section of the thin film transistor 300 formed by such method is shown in FIG. 3. Fabrication of the thin film transistor 300 mainly requires four masks in forming a pattern layer 301, a first conductor layer 305, a transparent oxide pattern 309, and a second conductor layer 315, respectively. While a PMOS transistor is used here as an example, the invention is not limited thereto, being equally applicable to NMOS or CMOS thin film transistors.

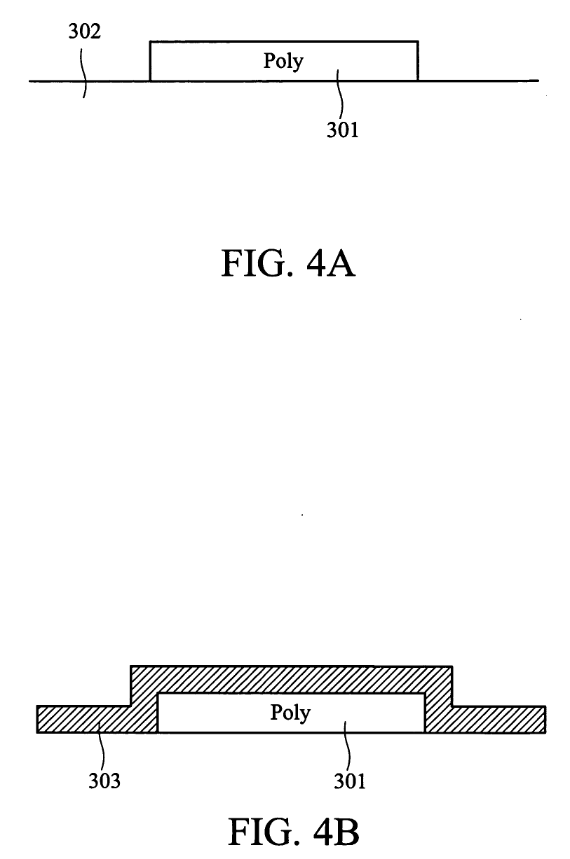

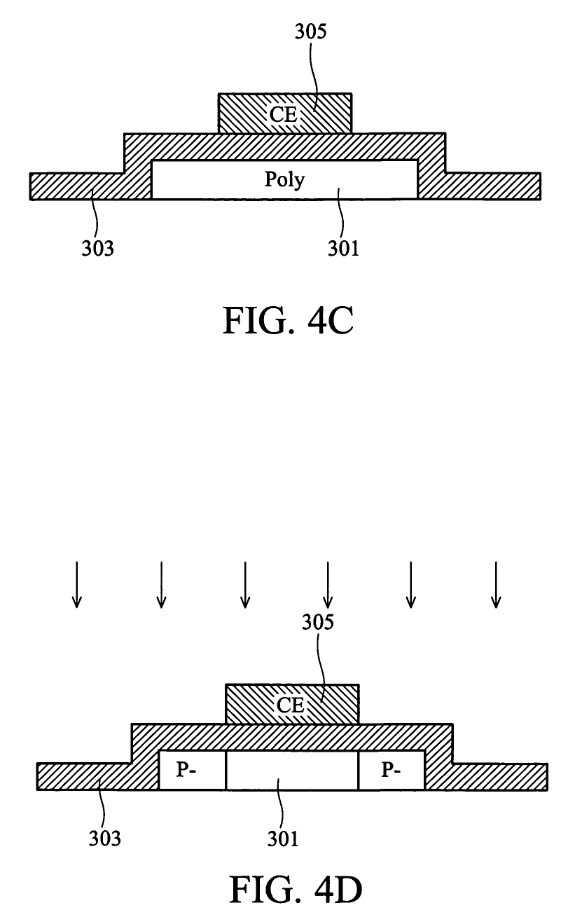

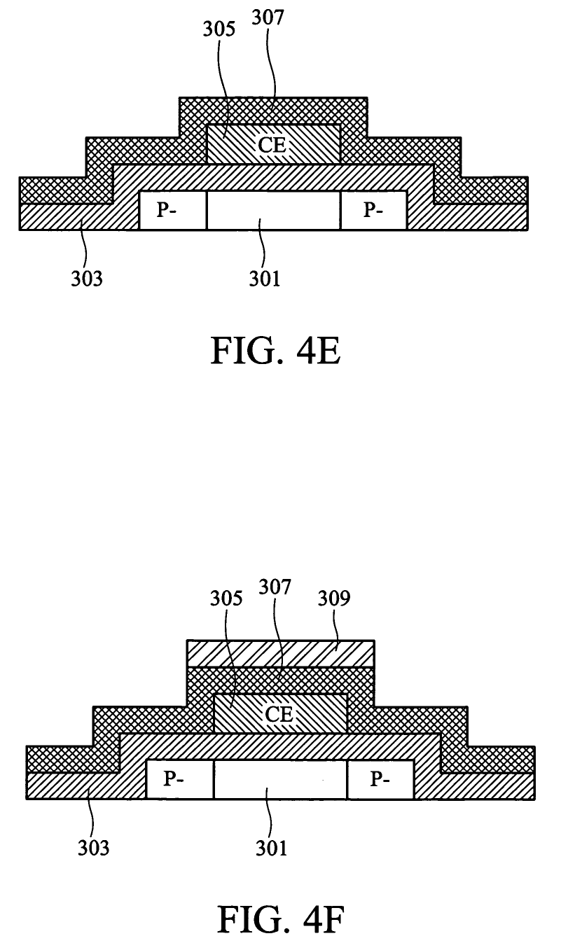

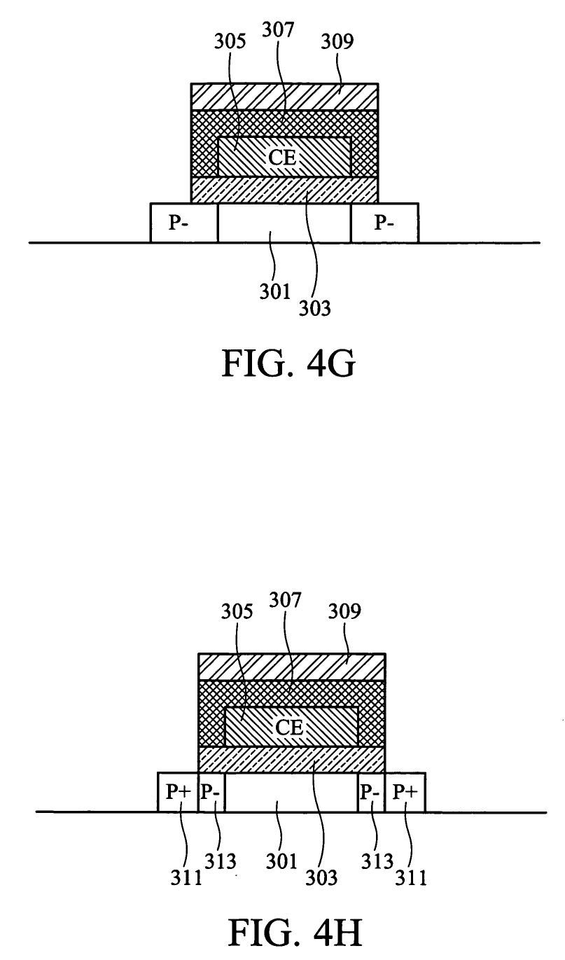

FIGS. 4A-4I collectively show a method of forming a thin film transistor according to an embodiment of the invention. FIG. 4A shows a first mask used in forming a pattern layer 301, poly-silicon or amorphous silicon, on a substrate 302. Preferably, the pattern layer is formed by amorphous silicon or poly-silicon with an excimer laser and lithography and etching processes with the first mask. As shown in FIG. 4B, a gate dielectric layer 303, oxide, nitride or combinations thereof, is formed over the pattern layer 301. Thereafter, a conducting material is deposited on the gate dielectric layer 303 and lithography and etching processes are performed with a second mask. Thus, a first conductor layer 305 is formed on the gate dielectric layer 303. Preferably, the first conductor layer 305 is a metal layer, as shown in FIG. 4C. Following formation of the first conductor layer 305, a self-aligned low-dose doping process, approximately 10¹¹˜10¹³ ions/cm², is performed on the pattern layer 301. Preferably, the doping process comprises ion implantation, as shown in FIG. 4D. An interlayer dielectric layer 307 is subsequently formed on the first conductor layer 305 and the gate dielectric layer 303, as shown in FIG. 4E. Before formation of the interlayer dielectric layer 307, dopant activation can be performed. Alternatively, dopant activation can be performed after a subsequent high-dose doping process. A transparent oxide layer is formed on the interlayer dielectric layer 307 and a third mask is used in lithography and etching. Thus, a transparent oxide pattern 309 is formed on the interlayer dielectric layer 307, as shown in FIG. 4F. Preferably, the transparent oxide pattern 309 can be Indium-Tin-Oxide(ITO), Indium-Zinc-Oxide(IZO), or Cadmium-Zinc-Oxide(CZO). The transparent oxide pattern 309 acts as a hard mask for self-aligned etching of the interlayer dielectric layer 307 and the gate dielectric layer 303 such that a portion of the lightly-doped pattern layer 301 is exposed, as shown in FIG. 4G. A high-dose doping process, approximately 10¹³˜10¹⁶ ions/cm², is performed to form source/drain regions 311 in the exposed pattern layer 301, such that lightly-doped regions 313 are defined. Width of the lightly-doped regions 313 can be modulated by controlling the size of the transparent oxide pattern 309, as shown in FIG. 4H. After the high-dose doping, dopant activation is required. If high temperatures are incompatible with the substrate, dopant activation is performed at low temperature. Finally, a second conductor layer 315 is deposited and a fourth mask used in etching the second conductor layer 315 and interconnections to the source/drain regions are thus formed, as shown in FIG. 4I.

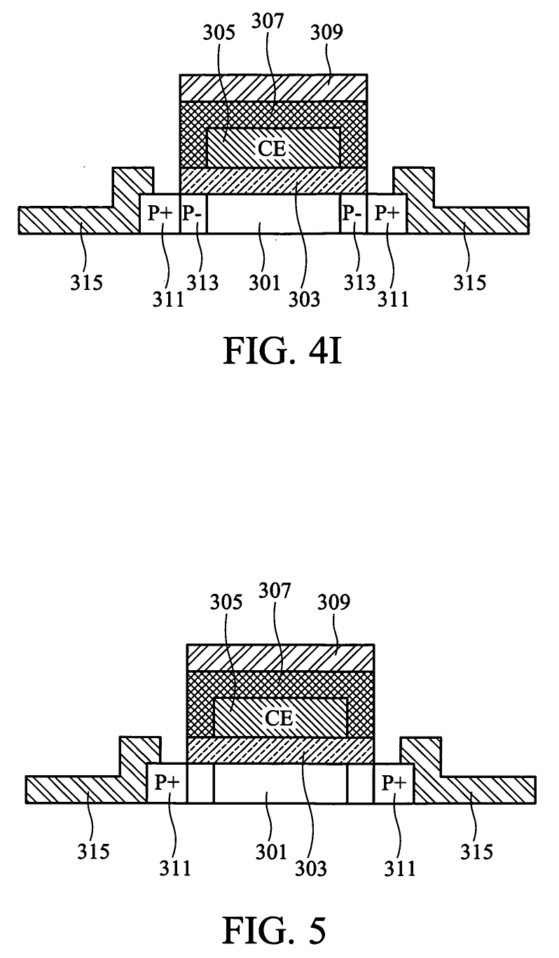

Another embodiment of the invention provides another method of forming a thin film transistor on a substrate. A cross section of the thin film transistor 500 formed by such method is shown in FIG. 5. The thin film transistor 500 has a top-gate structure with no lightly-doped drain structure. Fabrication thereof is similar to the disclosed method but differs in that a self-aligned low-dose doping process as shown in FIG. 4D is omitted. Despite the thin film transistor 500 having no lightly-doped draih regions, carrier accumulation at a surface of the poly-silicon layer can be induced as long as an appropriate bias is applied to the transparent oxide pattern 309. As a result, electrically equivalent lightly-doped drain regions are formed. This type of thin film transistor device is referred to as a filed plate thin film transistor.

The invention utilizes a transparent oxide pattern in performing self-aligned etching and doping. The process is simplified and number of masks required is reduced. Furthermore, the transparent oxide pattern is utilized to define the lightly-doped drain regions.

While the invention has been described by way of example and in terms of preferred embodiment, it is to be understood that the invention is not limited thereto. To the contrary, it is intended to cover various modifications and would be apparent to those skilled in the art. Therefore, the scope of the appended claims should be accorded the broadest interpretation so as to encompass all such modifications.

What is claimed is:

1. A method of forming a thin film transistor on a substrate comprising:
forming a pattern layer on the substrate;
forming a gate dielectric layer over the pattern layer on the substrate;
forming a first conductor pattern on the gate dielectric layer;
forming an interlayer dielectric layer on the first conductor pattern and the gate dielectric layer;
forming a transparent oxide pattern on the interlayer dielectric layer ;
etching the interlayer dielectric layer and the gate dielectric layer;
doping the pattern layer at high dosage to form source/drain regions; and
forming second conductor patterns respectively in contact with the source/drain regions.

2. The method of claim 1, wherein the pattern layer is doped with concentration from about 10¹³ ions/cm² to about 10¹⁶ ions/cm².

3. The method of claim 1, further comprising doping the pattern layer after formation of the first conductor pattern.

4. The method of claim 3, wherein the pattern layer is doped with concentration from about 10¹¹ ions/cm² to about 10¹³ ions/cm².

5. The method of claim 2, wherein doping the pattern layer comprises conducting ion implantation.

5. The method of claim 3, wherein doping the pattern layer comprises conducting ion implantation.

6. The method of claim 4, wherein doping the pattern layer comprises forming lightly-doped drain regions, with widths thereof modulated by size of the transparent oxide pattern.

7. The method of claim 1, wherein the transparent oxide pattern comprises the material of Indium-Tin-Oxide (ITO), Indium-Zinc-Oxide(IZO), or Cadmium-Zinc-Oxide(CZO).

8. The method of claim 1, wherein the formation of the pattern layer comprises:
forming a silicon layer on the substrate;
recrystallizing the silicon layer so as to convert the silicon layer into a poly-silicon layer; and
performing lithography and etching to pattern the poly-silicon layer.

9. The method of claim 1, wherein the silicon layer comprises a poly-silicon layer.

10. The method of claim 1, wherein the silicon layer comprises an amorphous silicon layer.

11. The method of claim 1, wherein the gate dielectric layer comprises a silicon oxide layer.

12. The method of claim 1, wherein the gate dielectric layer comprises a silicon nitride layer.
